(19) United States
(12) Patent Application Publication
(10) Pub. No.: US 2010/0002484 A1
(43) Pub. Date: Jan. 7, 2010

(54) Content addressable memory array with an invalidate feature

(75) Inventor: Christopher Gronlund, Kent, WA (US)

Correspondence Address: FARJAMI & FARJAMI LLP, 26522 LA ALAMEDA AVENUE, SUITE 360, MISSION VIEJO, CA, 92691, US

(73) Assignee: BROADCOM CORPORATION, IRVINE, CA (US)

(21) Appl. No.: 12/217,627

(22) Filed: Jul. 7, 2008

(51) Int. Cl. G11C 15/00

(52) U.S. Cl. 365/49.17

(57) ABSTRACT

A disclosed embodiment is a CAM (content addressable memory) array with an invalidate feature, the CAM array includes a plurality of words, where each of the plurality of words includes a respective invalidate circuit. Each respective invalidate circuit is configured to invalidate stored data in each corresponding plurality of words if compare data on a data input bus uniquely identifies, i.e. matches, the stored data. Each of the plurality of words is coupled to the data input bus. In one embodiment, each invalidate circuit includes a memory cell which stores a valid bit to configure the invalidate circuit to invalidate the stored data in a respective word. Each of the plurality of words further includes a respective plurality of CAM cells, which store the stored data. Each CAM cell outputs a match signal that is coupled to a latch. The match signals are also coupled to corresponding invalidate circuits.

### BACKGROUND OF THE INVENTION

1. Field if the Invention

The present invention is generally in the field of memory arrays. More particularly, the present invention relates to content addressable memory arrays.

2. Background Art

In addition to read and write operations, a conventional CAM (content addressable memory) array is typically configured to perform compare operations. During a compare operation, the CAM array compares data on an data input bus to stored data in every CAM array word simultaneously, and outputs the address of a CAM array word with matching stored data, if one exists. CAM arrays are thus useful in high-speed search applications. In some high-speed search applications, the CAM array is configured with an invalidate feature, such that after a compare operation, CAM array words with matching stored data are invalidated. Unfortunately, configuring a conventional CAM array for compare operations with such an invalidate feature typically results in a loss of performance.

For example, in order to implement an invalidate feature, a conventional CAM array can be configured to perform one or more write operations after a compare operation. In particular, after outputting the address of a CAM array word with matching stored data during a compare operation, a write operation can write an invalid bit to the same address. Because a write operation typically affects only one address at a time, multiple write operations must be performed to invalidate multiple CAM array words having matching stored data. Consequently, performance loss can become a serious factor in a conventional CAM array configured for compare operations with an invalidate feature in the manner described.

Thus, there is a need in the art for a CAM array that overcomes disadvantages associated with utilizing conventional CAM arrays for compare operations with an invalidate feature.

### SUMMARY OF THE INVENTION

A CAM (content addressable memory) array with an invalidate feature, substantially as shown in and/or described in connection with at least one of the figures, and as set forth more completely in the claims.

### BRIEF DESCRIPTION OF THE DRAWINGS

FIG. 1 shows an example of a conventional CAM (content addressable memory) array word.

FIG. 2 shows an exemplary CAM array word with an invalidate feature, according to one embodiment of the present invention.

FIG. 3 shows timing diagrams for a CAM array word with an invalidate feature, according to one embodiment of the present invention.

### DETAILED DESCRIPTION OF THE INVENTION

The present invention is directed to a CAM (content addressable memory) array with an invalidate feature. Although the invention is described with respect to specific embodiments, the principles of the invention, as defined by the claims appended herein, can obviously be applied beyond the specific embodiments of the invention described herein. Moreover, in the description of the present invention, certain details have been left out in order to not obscure the inventive aspects of the invention. The details left out are within the knowledge of a person of ordinary skill in the art.

The drawings in the present application and their accompanying detailed description are directed to merely exemplary embodiments of the invention. To maintain brevity, other embodiments of the invention which use the principles of the present invention are not specifically described in the present application and are not specifically illustrated by the present drawings.

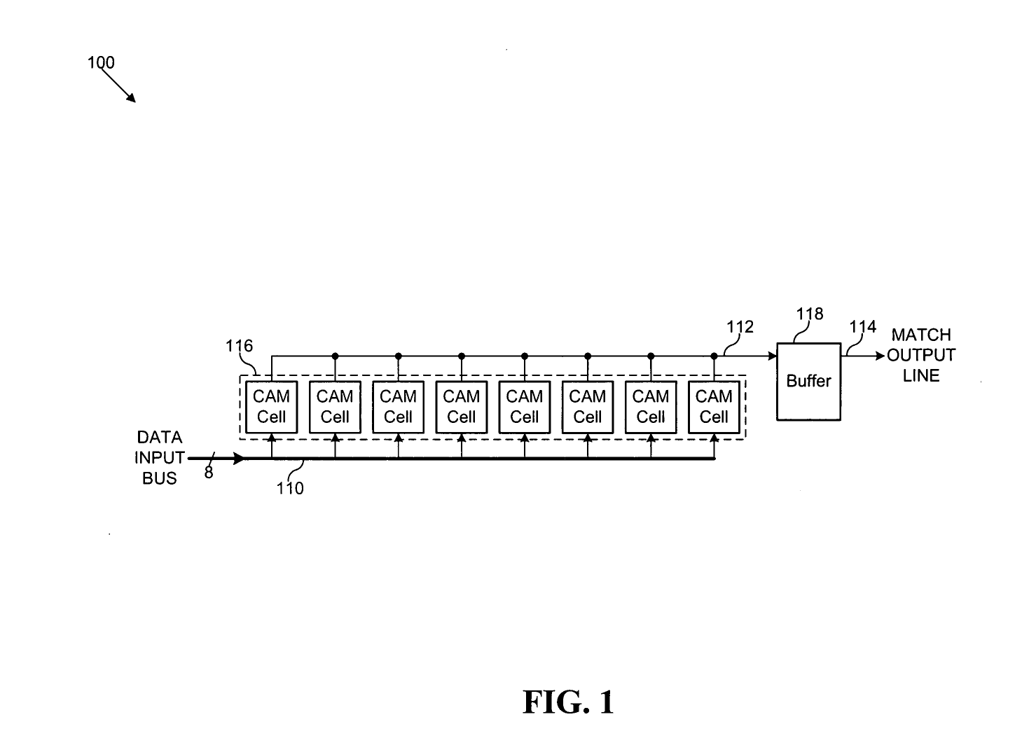

A conventional CAM (content addressable memory) array word is shown in FIG. 1 as word 100. Word 100 comprises CAM cells 116 and buffer 118. CAM cells 116 comprises eight individual CAM cells, each of which is coupled to a bit line of data input bus 110. Each individual CAM cell of CAM cells 116 is also coupled to cell match line 112, which is a single line and which is also coupled to buffer 118. Buffer 118 is also coupled to match output line 114. To implement compare operations with an invalidate feature utilizing word 100, one individual CAM cell of the eight in CAM cells 116 is utilized to store a valid bit, while the other seven individual CAM cells are utilized to store data (“stored data”).

The valid bit and the stored data in CAM cells 116 can be compared to data on data input bus 110 (“compare data”) during a compare operation, and can be written with data on data input bus 110 during a write operation. A CAM array implemented with a plurality of CAM array words such as word 100 can perform a compare operation on every CAM array word simultaneously. However, the CAM array can perform a write operation on only one CAM array word at a time. The CAM array can implement a compare operation with an invalidate feature by combining compare and write operations, as discussed below.

To begin a compare operation with an invalidate feature, compare data is provided to every CAM array word in the CAM array, including word 100, simultaneously. Thus, each individual CAM cell of CAM cells 116 receives compare data via the bit lines of data input bus 110. If the valid bit or stored data in an individual CAM cell is not uniquely identified by (i.e., does not match) the compare data on a respective bit line, the individual CAM cell will couple cell match line 112 to ground, using, for example, a pull-down transistor as known in the art. Subsequently, buffer 118 attempts to charge cell match line 112. If the valid bit and the stored data in the individual CAM cells of CAM cells 116 are uniquely identified by the compare data on each respective bit line, the charge on cell match line 112 is maintained, thereby indicating a match to buffer 118. Buffer 118 will consequently indicate a match on match output line 114 by outputting, for example, a logical one.

To conclude the compare operation with an invalidate feature, the CAM array comprising word 100 outputs the addresses of CAM array words that were uniquely identified by the compare data on an address output bus (not shown) coupled to each CAM array word. The CAM array then proceeds to invalidate each such CAM array word. To invalidate word 100, for example, the CAM array performs a write operation to write an invalid value, e.g. logical zero, to the valid bit in CAM cells 116. Consequently, word 100 is no longer valid and will not be uniquely identified, i.e. matched, on subsequent compare operations.

Notably, each CAM array word having stored data matched by the compare data must be invalidated by a separate write operation, because as stated above a write operation affects only one CAM array word at a time. For example, if word 100 and another CAM array word are both uniquely identified by the compare data, then two write operations must be performed to invalidate each CAM array word. Thus, generally, multiple write operations must be performed to invalidate multiple CAM array words having matching stored data. Consequently, performance loss can become a serious factor in a conventional CAM array configured to perform compare operations with an invalidate feature in the manner described.

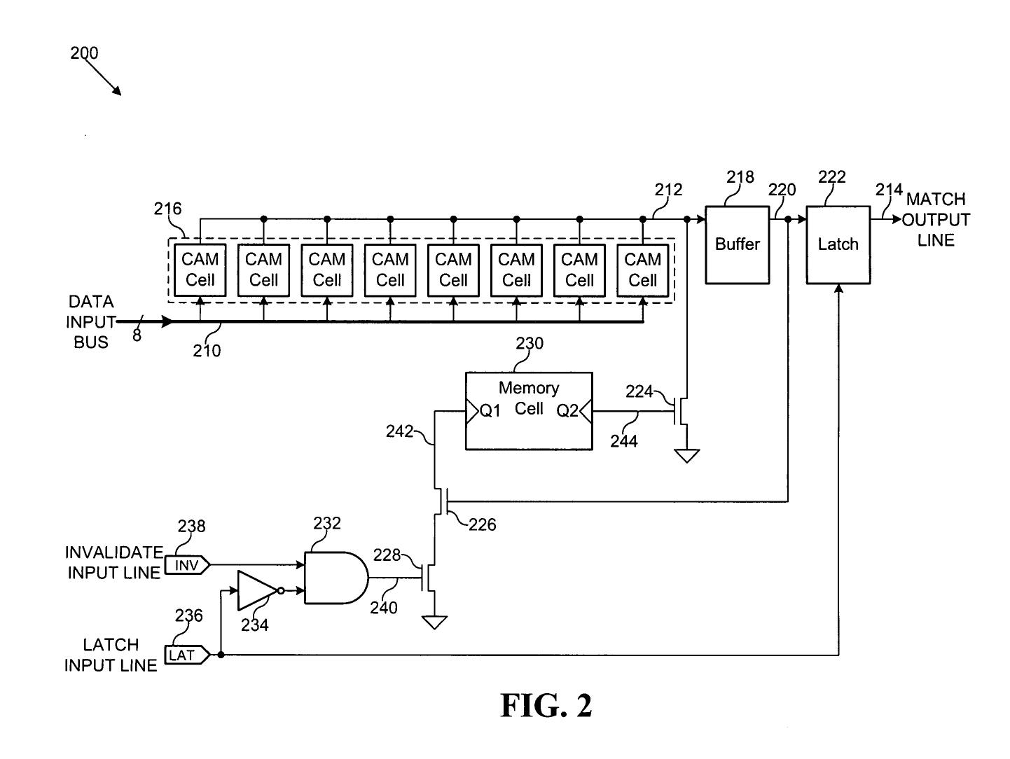

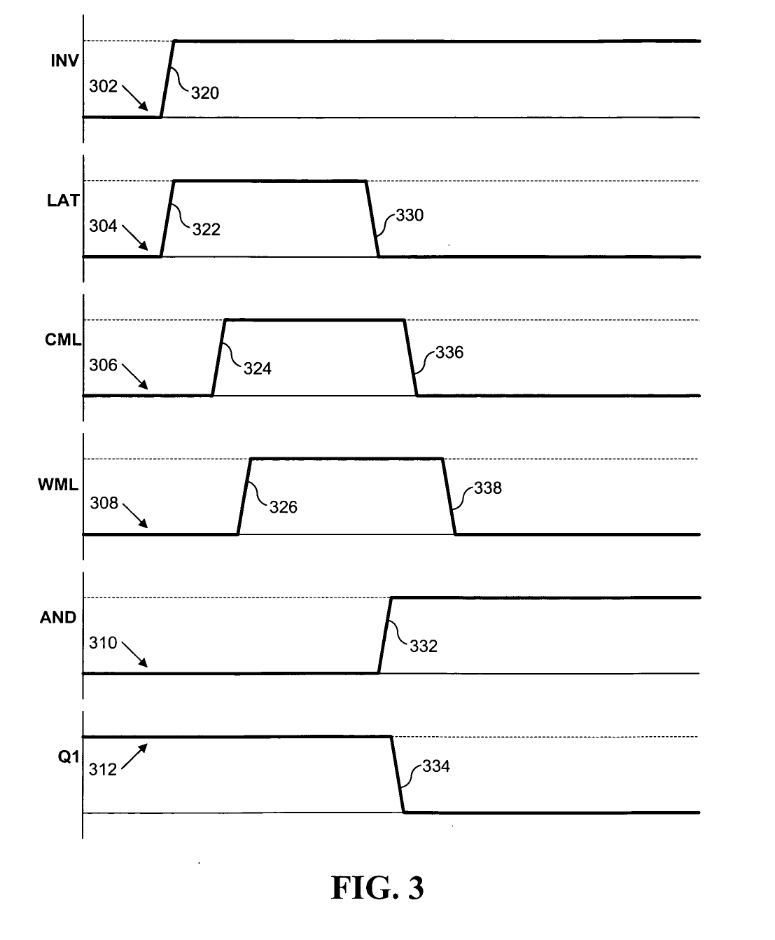

A CAM (content addressable memory) array word according to one embodiment of the present invention is shown in FIG. 2 as word 200. Timing diagrams 302, 304, 306, 308, 310, and 312 illustrating signals varying between logical one and zero voltages during a compare operation with an invalidate feature performed by word 200 are shown in FIG. 3. Word 200 comprises CAM cells 216, buffer 218, and an additional invalidate circuit that enables word 200 to perform such a compare operation, as described further below. CAM cells 216 comprises eight individual CAM cells in the present embodiment, but it is understood by those of ordinary skill in the art that the novel concepts explained in relation to word 200 can be easily extended and applied to a CAM array word having a different number of individual CAM cells in CAM cells 216. A CAM array implemented with a plurality of CAM array words such as word 200 can perform a compare operation on every CAM array word simultaneously, and can perform a write operation on one CAM array word at a time. Notably, however, such a CAM array according to the present invention can implement a compare operation with an invalidate feature solely with compare operations, as discussed below.

In the present exemplary embodiment, each individual CAM cell of CAM cells 216 comprises a compare logic and a pull-down transistor, as known in the art. Each individual CAM cell of CAM cells 216 is coupled to a bit line of data input bus 210 and outputs a match signal on cell match line 212. Buffer 218 is coupled to CAM cells 216 via cell match line 212 and provides an output on word match line 220. Word 200 also comprises latch 222, which outputs a logical value present on word match line 220 on match output line 214 while latch input line 236 is high, and latches the logical value when latch input line 236 transitions to low, as known in the art.

The invalidate circuit of word 200 comprises memory cell 230, which in one embodiment is implemented as two cross-coupled inverters, and transistors 224, 226, and 228. The Q2 terminal of memory cell 230 is coupled via line 244 to the gate of transistor 224. The source of transistor 224 is coupled to cell match line 212, while the drain of transistor 224 is coupled to ground. The Q1 terminal of memory cell 230 can be coupled to ground via transistor 226 and transistor 228, as shown in FIG. 2. The invalidate circuit of word 200 additionally comprises AND gate 232 and inverter 234. One input of AND gate 232 is coupled to invalidate input line 238, while the other input of AND gate 232 is coupled to latch input line 236 via inverter 234. The gate of transistor 228 is coupled to the output of AND gate 232 via line 240, while the gate of transistor 226 is coupled to word match line 220.

Prior to performing a compare operation on word 200, data (“stored data”) is stored in CAM cells 216 via a write operation. The write operation also sets the Q1 terminal of memory cell 230 to logical one, and sets the complementary Q2 terminal of memory cell 230 to logical zero, via write circuitry not shown in FIG. 2. The valid bit thus stored in memory cell 230 controls whether stored data in word 200 can be uniquely identified, i.e. matched, in compare operations. In particular, when the Q1 terminal is set to logical zero, i.e. when the valid bit of word 200 is not set, transistor 224 pulls down cell match line 212 to ground, such that CAM cells 216 cannot indicate a match on cell match line 212, as described further below.

In the beginning of a compare operation with an invalidate feature on word 200, the stored data is in CAM cells 216 and the valid bit is set in memory cell 230. Invalidate input line 238 is set high, as shown at rising edge 320 of timing diagram 302. At substantially the same time, latch 222 is enabled by setting latch input line 236 high, as shown at rising edge 322 of timing diagram 304 (latch input line 236 is later set low again after a preset gate delay). Subsequently, data (“compare data”) is provided to CAM cells 216 via the bit lines of data input bus 210. If the stored data in an individual CAM cell is not uniquely identified, i.e. not matched, by the compare data on a respective bit line, the individual CAM cell will couple cell match line 212 to ground, using, for example, a pull-down transistor. Notably, the present example utilizes binary logic circuits, such that data input bus 210 may uniquely identify, i.e. match, stored data in CAM cells 216 if and only if an exact binary match is found. Other embodiments of word 200 may instead use, for example, ternary logic, allowing for partial binary matches.

After word 200 compares the compare data to the stored data, buffer 218 attempts to charge cell match line 212, as shown by rising edge 324 of timing diagram 306. If cell match line 212 holds the charge, a unique identification, i.e. a matching, of the stored data of CAM cells 216 by the compare data is indicated to buffer 218. Buffer 218 consequently indicates a match on word match line 220 by outputting a logical one, as shown in timing diagram 308 at rising edge 326. Latch 222, previously enabled by the signal on latch input line 236 as shown in timing diagram 304, thus outputs the logical one signal present on word match line 220 on match output line 214. Notably, word match line 220 is also coupled to the gate of transistor 226, as stated above. Consequently, the logical one value on word match line 220 causes transistor 226 to couple the Q1 terminal of memory cell 230 to transistor 228.

After a preset gate delay, latch input line 236 is set back to logical zero, as shown in falling edge 330 of timing diagram 304. Latch 222 is thus disabled, and continues to output the latched logical one value on match output line 214. The return of latch input line 236 to logical zero also affects the output of AND gate 232 at line 240. In particular, the signal on the output of AND gate 232 at line 240 during a compare operation with an invalidate feature is shown in timing diagram 310, and results from performing a logical “and” operation on timing diagram 302 and an inverted timing diagram 304. As seen in timing diagram 310 at rising edge 332, the signal on line 240 rises after the signal on latch input line 236 returns to logical zero at falling edge 330, i.e. after latch 222 is disabled. Transistor 228 thus couples transistor 226 to ground. Because transistor 226 is still enabled by the logical one on word match line 220, as stated above, the Q1 terminal of memory cell 230 is thus coupled to ground via transistors 228 and 226. The Q1 terminal is thus pulled down to ground, as shown at falling edge 334 of timing diagram 312. The complementary Q2 terminal of memory cell 230 is thus set to logical one, coupling cell match line 212 to ground via transistor 224.

As cell match line 212 is coupled to ground via transistor 224, cell match line 212 is discharged as shown at falling edge 336 of timing diagram 306. A match, i.e. a unique identification, is thus no longer indicated to buffer 218, which sets word match line 220 low, as shown at falling edge 338 of timing diagram 308. Notably, because latch input line 236 was set low previously, at falling edge 330 of timing diagram 304, the change in word match line 220 is not latched by latch 222. Instead, the match indicated by word 200 prior to setting the valid bit in memory cell 230 to a logical zero continues to be output on match output line 214.

To conclude the compare operation with an invalidate feature, the CAM array comprising word 200 outputs the addresses of CAM array words that were uniquely identified by the compare data on an address output bus (not shown) coupled to each CAM array word. Notably, because each such CAM array word was invalidated by the operation of an invalidate circuit as described above, no further action to invalidate each such CAM array word is taken. Because the valid bit in memory cell 230, for example, was set to invalid during the compare operation, word 200 is no longer valid and will not be uniquely identified, i.e. matched, on subsequent compare operations. This is so because although CAM cells 216 will not pull down cell match line 212, transistor 224, coupled to memory cell 230, will. To make word 200 valid again, a subsequent write operation must reset the valid bit of memory cell 230 to a logical one.

In the manner described above, the present example's word 200 can perform a compare operation with an invalidate feature. Notably, each CAM array word in a CAM array according to the present example having stored data matched by the compare data does not need to be invalidated by a separate write operation following the compare operation. Instead, an invalidate circuit of each CAM array word invalidates stored data in each CAM array word as appropriate during the compare operation. Consequently, performance loss is avoided in a CAM array configured to perform compare operations with an invalidate feature according to the invention.

From the above description of the invention it is manifest that various techniques can be used for implementing the concepts of the present invention without departing from its scope. Moreover, while the invention has been described with specific reference to certain embodiments, a person of ordinary skill in the art would recognize that changes can be made in form and detail without departing from the spirit and the scope of the invention. The described embodiments are to be considered in all respects as illustrative and not restrictive. It should also be understood that the invention is not limited to the particular embodiments described herein, but is capable of many rearrangements, modifications, and substitutions without departing from the scope of the invention.

1. A CAM (content addressable memory) array with an invalidate feature, said CAM array comprising:
at least one word comprising an invalidate circuit;
wherein said invalidate circuit is configured to invalidate stored data in said at least one word if compare data on a data input bus matches said stored data.

2. The CAM array of claim 1, wherein said at least one word is coupled to said data input bus.

3. The CAM array of claim 1, wherein said invalidate circuit comprises a memory cell.

4. The CAM array of claim 3, wherein a valid bit in said memory cell configures said invalidate circuit to invalidate stored data in said at least one word.

5. The CAM array of claim 1, wherein said at least one word further comprises a plurality of CAM cells.

6. The CAM array of claim 5, wherein said stored data resides in said plurality of CAM cells.

7. The CAM array of claim 5, wherein said plurality of CAM cells output a match signal.

8. The CAM array of claim 7, wherein said match signal is coupled to a latch.

9. The CAM array of claim 7, wherein said match signal is coupled to said invalidate circuit.

10. The CAM array of claim 1, wherein said invalidate circuit is coupled to an invalidate input line.

11. A CAM (content addressable memory) array word comprising an invalidate circuit configured to invalidate stored data in said CAM array word if compare data on a data input bus matches said stored data.

12. The CAM array word of claim 11, wherein said CAM array word is coupled to said data input bus.

13. The CAM array word of claim 11, wherein said invalidate circuit comprises a memory cell.

14. The CAM array word of claim 13, wherein a valid bit in said memory cell configures said invalidate circuit to invalidate stored data in said CAM array word.

15. The CAM array word of claim 11, wherein said CAM array word further comprises a plurality of CAM cells.

16. The CAM array word of claim 15, wherein said stored data resides in said plurality of CAM cells.

17. The CAM array word of claim 15, wherein said plurality of CAM cells output a match signal.

18. The CAM array word of claim 17, wherein said match signal is coupled to a latch.

19. The CAM array word of claim 17, wherein said match signal is coupled to said invalidate circuit.

20. The CAM array word of claim 11, wherein said invalidate circuit is coupled to an invalidate input line.
